(19) United States
(12) Patent Application Publication
(10) Pub. No.: US 2026/0230055 A1
(43) Pub. Date: Aug. 6, 2026

(54) ACOUSTIC WAVE DEVICE

(71) Applicant: Murata Manufacturing Co., Ltd., Nagaokakyo-shi (JP)

(72) Inventor: Ibuki KUNORI, Nagaokakyo-shi (JP)

(21) Appl. No.: 19/529,627

(22) Filed: Feb. 4, 2026

(30) Foreign Application Priority Data
Feb. 5, 2025 (JP) 2025-017685

(51) Int. Cl. H03H 9/13; H03H 9/17; H03H 9/56

(52) U.S. Cl. CPC H03H 9/133; H03H 9/17; H03H 9/568

(57) ABSTRACT

An acoustic wave device includes first and second IDT electrodes and first, second, third, and fourth reflectors on a piezoelectric substrate. When a direction orthogonal to a direction in which reflector electrode fingers in the second reflector extend is defined as an orthogonal direction, reflector electrode fingers in the second and third reflectors overlap each other in the orthogonal direction. When M is defined as a median of all of center-to-center distances between the reflector electrode fingers adjacent to each other of the second and third reflectors, a mean value of the center-to-center distances within a range of M±about 40% is defined as a mean center-to-center distance, and λa<λb, where λa and λb wavelengths defined by the mean center-to-center distance in the second and third reflectors. A distance between the second and third reflectors is a distance Xn within a range represented by:

$$\frac{λ a + λ b}{4} \times n \times \frac{λ a}{λ b} < Xn < \frac{λ a + λ b}{4} \times n \times \frac{λ b}{λ a} . \qquad Formula 1$$

### CROSS REFERENCE TO RELATED APPLICATIONS

This application claims the benefit of priority to Japanese Patent Application No. 2025-017685 filed on Feb. 5, 2025. The entire contents of this application are hereby incorporated herein by reference.

### BACKGROUND OF THE INVENTION

### 1. Field of the Invention

The present invention relates to acoustic wave devices.

### 2. Description of the Related Art

Conventionally, acoustic wave devices have been widely used in filters for cellular phones and the like. An example of the acoustic wave device is disclosed in U.S. Patent Application Publication No. 2023/0006125. In this acoustic wave device, a plurality of interdigital transducer (IDT) electrodes are disposed on a piezoelectric layer. Thus, a plurality of acoustic wave resonators are formed. An acoustic wave leaks from each of the acoustic wave resonators. When the leaked acoustic waves are acoustically coupled to each other, unwanted waves are amplified and a filter characteristics degrades in some cases. In the acoustic wave device of U.S. Patent Application Publication No. 2023/0006125, an acoustic obstacle is disposed between the acoustic wave resonators to reduce or prevent the acoustic coupling.

However, in the acoustic wave device described in U.S. Patent Application Publication No. 2023/0006125, in order to reduce or prevent the amplification of unwanted waves caused by the acoustic coupling, a region for disposing the acoustic obstacle is required. Accordingly, in a case of attempting to reduce or prevent the acoustic coupling and reduce or prevent the degradation of the filter characteristic, it becomes difficult to reduce the size of the acoustic wave device.

### SUMMARY OF THE INVENTION

Example embodiments of the present invention provide acoustic wave devices each able to reduce or prevent degradation of a filter characteristics and achieve size reduction.

An acoustic wave device according to an example embodiment of the present invention includes a piezoelectric substrate including a piezoelectric layer, a first IDT electrode on the piezoelectric layer, and a second IDT electrode on the piezoelectric layer. The acoustic wave device also includes a first reflector and a second reflector on the piezoelectric layer and opposed to each other with the first IDT electrode interposed therebetween, and each includes a plurality of reflector electrode fingers. The acoustic wave device also includes a third reflector and a fourth reflector on the piezoelectric layer and opposed to each other with the second IDT electrode interposed therebetween, and each include a plurality of reflector electrode fingers. Of the first reflector and the second reflector, the second reflector is located on the second IDT electrode side. Of the third reflector and the fourth reflector, the third reflector is located on the first IDT electrode side. When a direction orthogonal or substantially orthogonal to a direction in which the plurality of reflector electrode fingers in the second reflector extend is defined as an orthogonal direction, the plurality of reflector electrode fingers in the second reflector and the plurality of reflector electrode fingers in the third reflector overlap each other in the orthogonal direction. When M is defined as a median of all of center-to-center distances between the reflector electrode fingers adjacent to each other as a plurality of pairs of the reflector electrode fingers in each of the second reflector and the third reflector, a mean value of the center-to-center distances within a range of M±about 40% is defined as a mean center-to-center distance, and λa<λb, where λa is a wavelength defined by the mean center-to-center distance in the second reflector and λb is a wavelength defined by the mean center-to-center distance in the third reflector. A distance between the second reflector and the third reflector is denoted as a distance Xn within a range represented by the following Formula 1, where n is any natural number:

$$\frac{λ a + λ b}{4} \times n \times \frac{λ a}{λ b} < Xn < \frac{λ a + λ b}{4} \times n \times \frac{λ b}{λ a} . \qquad Formula 1$$

With the acoustic wave devices according to example embodiments of the present invention, degradation of filter characteristics is reduced or prevented and size reduction is achieved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of an acoustic wave device according to a first example embodiment of the present invention.

FIG. 2 is a schematic plan view showing a first acoustic wave resonator and a second acoustic wave resonator in the acoustic wave device according to the first example embodiment of the present invention.

FIG. 3 is a simplified sectional view taken along line I-I in FIG. 2.

FIG. 4 is a diagram showing an attenuation-frequency characteristic in the first example embodiment of the present invention and in a first comparative example.

FIG. 5 is a diagram showing a relationship between a distance between a second reflector and a third reflector and a frequency at which a ripple due to acoustic coupling occurs.

FIG. 6 is a diagram showing the attenuation-frequency characteristic in a case in which a wavelength ratio λa/λb is about 0.98 and a wavelength ratio λb/λa is about 1.02 in the first example embodiment of the present invention and in the first comparative example.

FIG. 7 is a diagram showing the attenuation-frequency characteristic in a case in which n=3 in the first example embodiment of the present invention and in the first comparative example.

FIG. 8 is a diagram showing a relationship between a ratio R1 and the attenuation-frequency characteristic.

FIG. 9 is a diagram showing a relationship between the ratio R1 and an admittance-frequency characteristic.

FIG. 10 is a diagram showing a relationship between the ratio R1 and the magnitude of the ripple due to acoustic coupling.

FIG. 11 is a schematic plan view showing a portion of a first IDT electrode and the second reflector in the first example embodiment of the present invention.

FIG. 12 is a schematic plan view showing a first acoustic wave resonator and a second acoustic wave resonator in an acoustic wave device according to a second example embodiment of the present invention.

FIG. 13 is a schematic plan view showing a first acoustic wave resonator and a second acoustic wave resonator in an acoustic wave device according to a third example embodiment of the present invention.

FIG. 14 is a schematic plan view showing a first acoustic wave resonator and a second acoustic wave resonator in an acoustic wave device according to a fourth example embodiment of the present invention.

### DETAILED DESCRIPTION OF THE EXAMPLE EMBODIMENTS

In the following, the present invention is made apparent by describing specific example embodiments of the present invention with reference to the drawings.

The respective example embodiments described in the present specification are provided as examples, and partial replacement or combination of configurations between different example embodiments is possible.

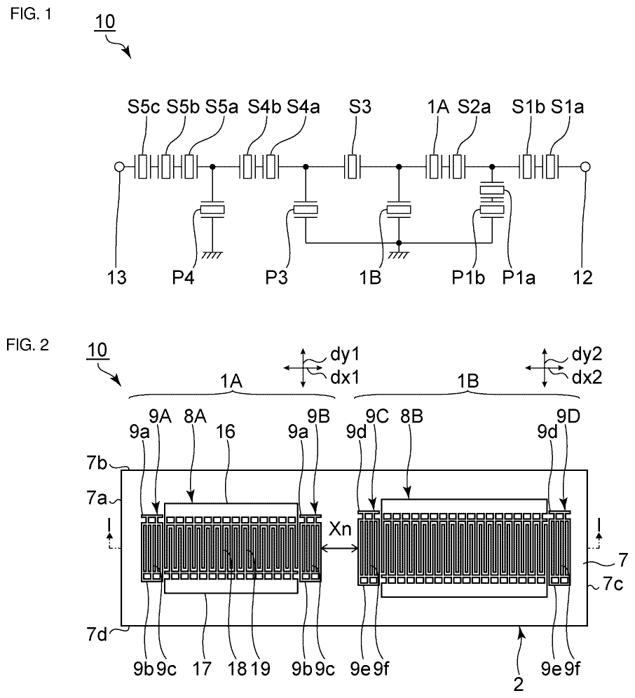

FIG. 1 is a circuit diagram of an acoustic wave device according to a first example embodiment of the present invention.

An acoustic wave device 10 is a filter device. Specifically, the acoustic wave device 10 is a ladder filter including a plurality of series-arm resonators and a plurality of parallel-arm resonators. More specifically, the acoustic wave device 10 is, for example, a transmission filter. However, the acoustic wave device 10 is not limited to the transmission filter. The acoustic wave device 10 may be, for example, a reception filter.

A pass band of the acoustic wave device 10 is, for example, a transmission band of Band 66, which ranges from about 1710 MHz to about 1780 MHz. The pass band of the acoustic wave device 10 is not limited to the above.

In the present example embodiment, all of the series-arm resonators and all of the parallel-arm resonators are acoustic wave resonators. The plurality of series-arm resonators in the acoustic wave device 10 include a first acoustic wave resonator 1A. The plurality of parallel-arm resonators in the acoustic wave device 10 include a second acoustic wave resonator 1B. However, the first acoustic wave resonator 1A may be a parallel-arm resonator. The second acoustic wave resonator 1B may be a series-arm resonator.

FIG. 2 is a schematic plan view showing the first acoustic wave resonator and the second acoustic wave resonator in the acoustic wave device according to the first example embodiment. In FIG. 2, the acoustic wave resonators other than the first acoustic wave resonator 1A and the second acoustic wave resonator 1B and wiring lines are omitted. In FIG. 2, a piezoelectric substrate described later is shown in a simplified manner. The same applies to the schematic plan views other than FIG. 2.

The first acoustic wave resonator 1A and the second acoustic wave resonator 1B are disposed adjacent to each other. The acoustic wave devices 10 according to example embodiments of the present invention are only required to include at least the first acoustic wave resonator 1A and the second acoustic wave resonator 1B adjacent to each other. The acoustic wave device 10 according to example embodiments of the present invention are not limited to a filter device such as a transmission filter or a reception filter. The acoustic wave device 10 may be, for example, an element used in a filter device.

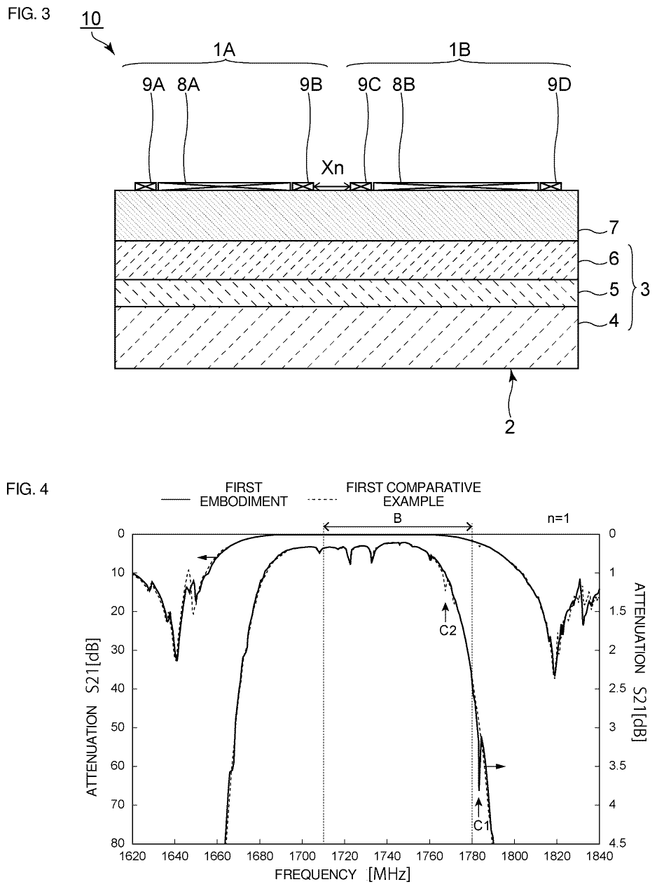

FIG. 3 is a simplified sectional view taken along line I-I in FIG. 2. In FIG. 3, each IDT electrode and each reflector described later are shown by a simplified figure obtained by adding two diagonal lines to a rectangle.

The acoustic wave device 10 includes a piezoelectric substrate 2. The piezoelectric substrate 2 has piezoelectricity. The piezoelectric substrate 2 includes a support 3 and a piezoelectric layer 7. In the present example embodiment, the support 3 includes a support substrate 4, a first intermediate layer 5, and a second intermediate layer 6. The first intermediate layer 5 is disposed on the support substrate 4. The second intermediate layer 6 is disposed on the first intermediate layer 5. The piezoelectric layer 7 is disposed on the second intermediate layer 6. In this manner, the piezoelectric layer 7 is indirectly disposed over the support substrate 4 with the first intermediate layer 5 and the second intermediate layer 6 interposed therebetween.

The support 3 may include only the support substrate 4. In this case, it is sufficient that the piezoelectric layer 7 is directly disposed on the support substrate 4. Alternatively, the piezoelectric substrate 2 is not required to include the support 3, and may include only the piezoelectric layer 7.

In the present example embodiment, a combination of materials of the support substrate 4/the first intermediate layer 5/the second intermediate layer 6/the piezoelectric layer 7 as a multilayer body is, for example, silicon/silicon nitride/silicon oxide/lithium tantalate. However, the materials of the support substrate 4, the first intermediate layer 5, the second intermediate layer 6, and the piezoelectric layer 7 are not limited to those described above.

Referring back to FIG. 2, a first IDT electrode 8A, a first reflector 9A, and a second reflector 9B are disposed on the piezoelectric layer 7 in the piezoelectric substrate 2. This defines the first acoustic wave resonator 1A. Further, a second IDT electrode 8B, a third reflector 9C, and a fourth reflector 9D are disposed on the piezoelectric layer 7. This defines the second acoustic wave resonator 1B. As described above, the first acoustic wave resonator 1A and the second acoustic wave resonator 1B share the piezoelectric substrate 2, and share the piezoelectric layer 7.

In the first acoustic wave resonator 1A, an acoustic wave is excited by applying an alternating voltage to the first IDT electrode 8A. In the second acoustic wave resonator 1B, an acoustic wave is excited by applying an alternating voltage to the second IDT electrode 8B.

The first IDT electrode 8A includes a pair of busbars and a plurality of electrode fingers. Specifically, the pair of busbars include a first busbar 16 and a second busbar 17. The first busbar 16 and the second busbar 17 are opposed to each other. Specifically, the plurality of electrode fingers include a plurality of first electrode fingers 18 and a plurality of second electrode fingers 19. One end of each of the first electrode fingers 18 is connected to the first busbar 16. One end of each of the second electrode fingers 19 is connected to the second busbar 17. The first electrode fingers 18 and the second electrode fingers 19 are interdigitated with each other. The first electrode fingers 18 and the second electrode fingers 19 are connected to different potentials from each other. Hereinafter, the first busbar 16 and the second busbar 17 are sometimes collectively referred to simply as a busbar. The first electrode finger 18 and the second electrode finger 19 are sometimes collectively referred to simply as electrode finger.

The second IDT electrode 8B also includes a pair of busbars and a plurality of electrode fingers similarly to the first IDT electrode 8A. Hereinafter, a direction in which the plurality of electrode fingers extend is defined as an electrode finger extension direction, and a direction orthogonal or substantially orthogonal to the electrode finger extension direction is defined as an electrode finger orthogonal direction. In the acoustic wave device 10, the electrode finger extension direction in the first acoustic wave resonator 1A is parallel or substantially parallel to the electrode finger extension direction in the second acoustic wave resonator 1B. The electrode finger extension direction in the first acoustic wave resonator 1A and the electrode finger extension direction in the second acoustic wave resonator 1B are not necessarily required to be parallel or substantially parallel to each other.

The first reflector 9A and the second reflector 9B are opposed to each other with the first IDT electrode 8A interposed therebetween in the electrode finger orthogonal direction in the first IDT electrode 8A. The third reflector 9C and the fourth reflector 9D are opposed to each other with the second IDT electrode 8B interposed therebetween in the electrode finger orthogonal direction in the second IDT electrode 8B.

Of the first reflector 9A and the second reflector 9B, the second reflector 9B is located on the second IDT electrode 8B side. Of the third reflector 9C and the fourth reflector 9D, the third reflector 9C is located on the first IDT electrode 8A side. The second reflector 9B and the third reflector 9C are adjacent to each other.

The first reflector 9A includes a pair of reflector busbars and a plurality of reflector electrode fingers 9c. Specifically, the pair of reflector busbars include a first reflector busbar 9a and a second reflector busbar 9b. The first reflector busbar 9a and the second reflector busbar 9b are opposed to each other. One end of each of the reflector electrode fingers 9c is connected to the first reflector busbar 9a. The other end of each of the reflector electrode fingers 9c is connected to the second reflector busbar 9b. Similarly, the second reflector 9B also has the first reflector busbar 9a, the second reflector busbar 9b, and a plurality of reflector electrode fingers 9c.

The third reflector 9C includes a third reflector busbar 9d, a fourth reflector busbar 9e, and a plurality of reflector electrode fingers 9f. The third reflector busbar 9d and the fourth reflector busbar 9e are opposed to each other. One end of each of the reflector electrode fingers 9f is connected to the third reflector busbar 9d. The other end of each of the reflector electrode fingers 9f is connected to the fourth reflector busbar 9e. Similarly, the fourth reflector 9D also includes the third reflector busbar 9d, the fourth reflector busbar 9e, and a plurality of reflector electrode fingers 9f.

Hereinafter, a direction in which the plurality of reflector electrode fingers 9c in the first reflector 9A and the second reflector 9B extend is defined as a first extension direction dy1 as the extension direction. A direction orthogonal or substantially orthogonal to the first extension direction dy1 is defined as a first orthogonal direction dx1 as the orthogonal direction. A direction in which the plurality of reflector electrode fingers 9f in the third reflector 9C and the fourth reflector 9D extend is defined as a second extension direction dy2, and a direction orthogonal or substantially orthogonal to the second extension direction dy2 is defined as a second orthogonal direction dx2.

The first orthogonal direction dx1 is parallel or substantially parallel to the electrode finger orthogonal direction of the first IDT electrode 8A. Thus, it can also be said that the first reflector 9A and the second reflector 9B are opposed to each other with the first IDT electrode 8A interposed therebetween in the first orthogonal direction dx1. The second orthogonal direction dx2 is parallel or substantially parallel to the electrode finger orthogonal direction of the second IDT electrode 8B. Thus, the third reflector 9C and the fourth reflector 9D are opposed to each other with the second IDT electrode 8B interposed therebetween in the second orthogonal direction dx2.

In the first orthogonal direction dx1, the plurality of reflector electrode fingers 9c in the second reflector 9B and the plurality of reflector electrode fingers 9f in the third reflector 9C overlap each other. In the present example embodiment, the first orthogonal direction dx1 and the second orthogonal direction dx2 are parallel or substantially parallel to each other. Thus, also in the second orthogonal direction dx2, the plurality of reflector electrode fingers 9c in the second reflector 9B and the plurality of reflector electrode fingers 9f in the third reflector 9C overlap each other. However, the first orthogonal direction dx1 and the second orthogonal direction dx2 are not necessarily required to be parallel or substantially parallel to each other.

Hereinafter, the first IDT electrode 8A and the second IDT electrode 8B are sometimes collectively referred to simply as IDT electrode. The first reflector 9A, the second reflector 9B, the third reflector 9C, and the fourth reflector 9D are sometimes collectively referred to simply as reflector.

Each IDT electrode and each reflector in the present example embodiment includes a multilayer metal film. Specifically, for example, in each IDT electrode and each reflector, a Ti layer and an AlCu layer are laminated in that order from the piezoelectric layer 7 side. The materials of each IDT electrode and each reflector are not limited to those described above. Alternatively, each IDT electrode and each reflector may include a single-layer metal film.

In each of the first reflector 9A and the second reflector 9B of the acoustic wave device 10, a center-to-center distance in the first orthogonal direction dx1 between the adjacent reflector electrode fingers 9c is constant. Similarly, in each of the third reflector 9C and the fourth reflector 9D, a center-to-center distance in the second orthogonal direction dx2 between the adjacent reflector electrode fingers 9f is constant. Hereinafter, the center-to-center distance between the adjacent reflector electrode fingers 9c or the center-to-center distance between the adjacent reflector electrode fingers 9f is sometimes referred to simply as center-to-center distance. In example embodiments of the present invention, the center-to-center distance in each of the first reflector 9A, the second reflector 9B, the third reflector 9C, and the fourth reflector 9D is not necessarily required to be constant.

For example, a wavelength in the second reflector 9B can be defined by the center-to-center distances between the adjacent reflector electrode fingers 9c in the second reflector 9B. When the second reflector 9B includes m reflector electrode fingers 9c, the second reflector 9B has (m−1) pairs of the adjacent reflector electrode fingers 9c. In this case, the center-to-center distances in the second reflector 9B are the respective center-to-center distances between the (m−1) pairs of the adjacent reflector electrode fingers 9c.

When M is defined as a median of all of the center-to-center distances between the reflector electrode fingers 9c adjacent to each other as a plurality of pairs of the reflector electrode fingers 9c in the second reflector 9B, for example, a mean value of the center-to-center distances within a range of M±about 40% is defined as a mean center-to-center distance. For example, when all of the center-to-center distances are within the range of M±about 40%, the mean value of all the center-to-center distances is the mean center-to-center distance. On the other hand, for example, when some of the center-to-center distances are not within the range of M±about 40%, the center-to-center distances that are not within the range of M±about 40% are excluded in calculating the mean center-to-center distance. A wavelength defined by the mean center-to-center distance in the second reflector 9B is a wavelength λa in the second reflector 9B.

Similarly, when M is defined as a median of all of the center-to-center distances between the reflector electrode fingers 9f adjacent to each other as a plurality of pairs of the reflector electrode fingers 9f in the third reflector 9C, for example, a mean value of the center-to-center distances within a range of M±about 40% is defined as the mean center-to-center distance. A wavelength defined by the mean center-to-center distance in the third reflector 9C is a wavelength λb in the third reflector 9C.

In example embodiments of the present invention, λa<λb. When the mean center-to-center distance in the second reflector 9B is defined as pa, λa=about 2pa. When the mean center-to-center distance in the third reflector 9C is defined as pb, λb=about 2pb.

In the present specification, a wavelength defined by center-to-center distances between the adjacent electrode fingers of the first IDT electrode 8A is also a wavelength defined by the mean center-to-center distance calculated similarly to that of the second reflector 9B and the third reflector 9C. The same applies to the second IDT electrode 8B.

The present example embodiment has a configuration in which a distance between the second reflector 9B and the third reflector 9C is a distance Xn within a range represented by the following Formula 1, where n is any natural number. This makes it possible to reduce or prevent degradation of a filter characteristics of the acoustic wave device 10 and achieve size reduction of the acoustic wave device 10. Details thereof are described below together with a circuit configuration of the acoustic wave device 10.

$$\frac{λ a + λ b}{4} \times n \times \frac{λ a}{λ b} < Xn < \frac{λ a + λ b}{4} \times n \times \frac{λ b}{λ a} \qquad Formula 1$$

As shown in FIG. 1, the acoustic wave device 10 includes a first signal terminal 12 and a second signal terminal 13. The first signal terminal 12 and the second signal terminal 13 may be, for example, electrode pads or wiring lines. A plurality of series-arm resonators are connected in series with each other between the first signal terminal 12 and the second signal terminal 13.

Specifically, the plurality of series-arm resonators of the acoustic wave device 10 include a series-arm resonator Sla, a series-arm resonator S1b, a series-arm resonator S2a, the first acoustic wave resonator 1A, a series-arm resonator S3, a series-arm resonator S4a, a series-arm resonator S4b, a series-arm resonator S5a, a series-arm resonator S5b, and a series-arm resonator S5c. From the first signal terminal 12 side, these resonators are arranged in order of the series-arm resonator Sla, the series-arm resonator S1b, the series-arm resonator S2a, the first acoustic wave resonator 1A, the series-arm resonator S3, the series-arm resonator S4a, the series-arm resonator S4b, the series-arm resonator S5a, the series-arm resonator S5b, and the series-arm resonator S5c.

In the present example embodiment, the plurality of series-arm resonators include a plurality of series-arm resonators obtained by series division. Specifically, the series-arm resonator Sla and the series-arm resonator S1b are two series-arm resonators obtained by series division of one series-arm resonator in terms of circuit configuration. The series-arm resonator S2a and the first acoustic wave resonator 1A are two series-arm resonators obtained by series division of one series-arm resonator in terms of circuit configuration. The series-arm resonator S4a and the series-arm resonator S4b are two series-arm resonators obtained by series division of one series-arm resonator in terms of circuit configuration. The series-arm resonator S5a, the series-arm resonator S5b, and the series-arm resonator S5c are three series-arm resonators obtained by series division of one series-arm resonator in terms of circuit configuration.

In example embodiments of the present invention, each of the series-arm resonators obtained by series division is treated as one independent acoustic wave resonator. Each of series-arm resonators obtained by parallel division is also treated as one independent acoustic wave resonator. Similarly, each of parallel-arm resonators obtained by series division or parallel division is also treated as one independent acoustic wave resonator.

Specifically, the plurality of parallel-arm resonators of the acoustic wave device 10 include a parallel-arm resonator Pla, a parallel-arm resonator P1b, the second acoustic wave resonator 1B, a parallel-arm resonator P3, and a parallel-arm resonator P4. The parallel-arm resonator Pla and the parallel-arm resonator P1b are connected in series with each other between a connection point between the series-arm resonator S1b and the series-arm resonator S2a and a ground potential. The second acoustic wave resonator 1B is connected between a connection point between the first acoustic wave resonator 1A and the series-arm resonator S3 and the ground potential. The parallel-arm resonator P4 is connected between a connection point between the series-arm resonator S4b and the series-arm resonator S5a and the ground potential. The parallel-arm resonator P1b, the second acoustic wave resonator 1B, and the parallel-arm resonator P3 are commonly connected to the ground potential. The circuit configuration of the acoustic wave device 10 is not limited to that described above.

As described above, when acoustic waves leaked from a plurality of acoustic wave resonators are acoustically coupled to each other, unwanted waves are sometimes amplified. Due to such amplification of unwanted waves, for example, a ripple occurs in an attenuation-frequency characteristic or the like of the acoustic wave device as a filter device. In the first example embodiment, it is possible to reduce or prevent degradation of the filter characteristics of the acoustic wave device caused by the ripple due to the acoustic coupling. This is shown below by comparing the first example embodiment with a first comparative example.

A basic configuration of the first comparative example is the same or substantially the same as the configuration of the first example embodiment. The first comparative example is different from the first example embodiment in that the distance between the second reflector and the third reflector is not the distance Xn within the range represented by the above Formula 1. The attenuation-frequency characteristic was compared between the acoustic wave device 10 having the configuration of the first example embodiment and the acoustic wave device of the first comparative example. In this comparison, n was set to 1 in Formula 1. Example design parameters of the acoustic wave device 10 were set as follows:
Support substrate: material . . . Si, orientation angle . . . (111)
First intermediate layer: material . . . SiN, thickness . . . about 300 nm
Second intermediate layer: material . . . SiO₂, thickness . . . about 300 nm
Piezoelectric layer: material . . . 42° Y-cut LiTaO₃, thickness . . . about 400 nm
First IDT electrode, second IDT electrode, first reflector, second reflector, third reflector, and fourth reflector: material . . . Ti/AlCu from the piezoelectric layer side, thickness . . . about 12 nm/100 nm from the piezoelectric layer side
Wavelength defined by the mean center-to-center distance in the first IDT electrode: about 2.2498 μm
Wavelength defined by the mean center-to-center distance in the second IDT electrode: about 2.3944 μm
Wavelength defined by the mean center-to-center distance in the first reflector: about 2.3847 μm
Wavelength λa defined by the mean center-to-center distance in the second reflector: about 2.3847 μm
Wavelength λb defined by the mean center-to-center distance in the third reflector: about 2.4184 μm
Wavelength defined by the mean center-to-center distance in the fourth reflector: about 2.4184 μm

The design parameters of the acoustic wave device in the first comparative example were also set to be the same or substantially the same as those of the acoustic wave device 10 in the first example embodiment. However, as described above, the first comparative example was different from the first example embodiment in the distance between the second reflector and the third reflector.

FIG. 4 is a diagram showing the attenuation-frequency characteristic in the first example embodiment and the first comparative example. A double-headed arrow B in FIG. 4 indicates a pass band in the acoustic wave devices of the first example embodiment and in the first comparative example. This pass band ranges from about 1710 MHz to about 1780 MHz.

Arrows C1 and C2 in FIG. 4 indicate a ripple due to acoustic coupling between acoustic waves leaked from the first acoustic wave resonator and the second acoustic wave resonator. As indicated by the arrow C2, the ripple occurs near 1765 MHz in the first comparative example. Thus, in the first comparative example, the ripple due to acoustic coupling occurs in the pass band. In contrast, as indicated by the arrow C1, the ripple occurs near 1785 MHz in the first example embodiment. Thus, in the first example embodiment, the ripple due to acoustic coupling occurs outside the pass band.

In the first example embodiment, it is possible to reduce or prevent occurrence of the ripple due to acoustic coupling in the pass band. This can reduce or prevent degradation of the filter characteristics of the acoustic wave device 10. In addition, in the first example embodiment, as shown in FIG. 2, the above advantageous effect can be obtained without providing a structure between the first acoustic wave resonator 1A and the second acoustic wave resonator 1B. Accordingly, size reduction of the acoustic wave device 10 can be achieved.

Moreover, it is shown below that the occurrence of a ripple in the pass band is reduced or prevented by the distance between the second reflector 9B and the third reflector 9C being the distance Xn within the range represented by Formula 1.

$$\frac{λ a + λ b}{4} \times n \times \frac{λ a}{λ b} < Xn < \frac{λ a + λ b}{4} \times n \times \frac{λ b}{λ a} \qquad Formula 1$$

An examination was conducted using an acoustic wave device having basically the same configuration as that of the first example embodiment. In this examination, reference numerals used in the description of the first example embodiment are applied. In this acoustic wave device, a frequency at which the ripple due to acoustic coupling occurs was measured each time the distance between the second reflector 9B and the third reflector 9C was varied. The distance between the second reflector 9B and the third reflector 9C was varied both within and outside the range represented by Formula 1. Thus, a relationship between the above distance and the frequency at which the ripple due to acoustic coupling occurs was derived. Design parameters of this acoustic wave device, except for the above distance, were set to be the same or substantially the same as those of the acoustic wave device 10 in the first example embodiment relating to the comparison shown in FIG. 4.

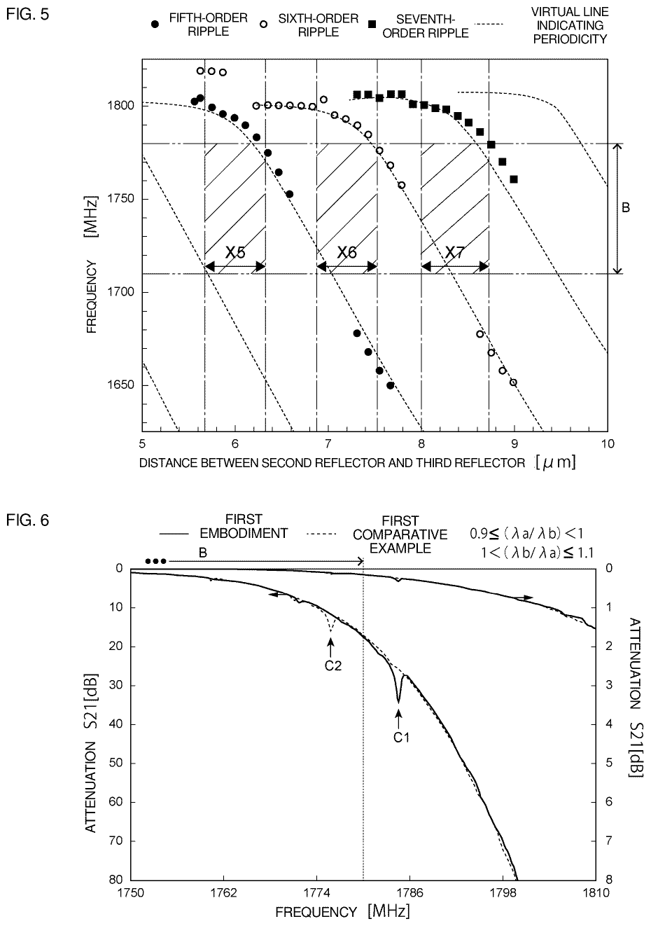

As a result of this examination, it was discovered that unwanted waves of a plurality of modes are amplified by acoustic coupling and a ripple occurs. In addition, it was discovered that a large ripple due to acoustic coupling periodically occurs with respect to the distance between the second reflector 9B and the third reflector 9C. Further, it was discovered that the order of unwanted waves greatly amplified by acoustic coupling differs depending on the above distance. Hereinafter, for example, a ripple caused by amplification of unwanted waves of an n-th-order mode due to acoustic coupling is sometimes referred to simply as n-th-order ripple. In FIG. 5 below, frequencies at which fifth-, sixth-, and seventh-order ripples occur are indicated.

FIG. 5 is a diagram showing a relationship between the distance between the second reflector and the third reflector and the frequency at which the ripple due to acoustic coupling occurs. A double-headed arrow B in FIG. 5 indicates a pass band of the acoustic wave device relating to this examination. A range indicated by a double-headed arrow given reference numeral X5 in FIG. 5 represents a range of the distance Xn when n=5 in Formula 1. Similarly, a range indicated by a double-headed arrow given reference numeral X6 represents a range of the distance Xn when n=6, and a range indicated by a double-headed arrow given reference numeral X7 represents a range of the distance Xn when n=7. In addition, in FIG. 5, hatching is applied to a range in which the distance between the second reflector 9B and the third reflector 9C is within the range of the distance X5 and the frequency is within the pass band. Similarly, hatching is also applied to ranges in which the above distance is within the range of the distance X6 or X7 and the frequency is within the pass band.

As shown in FIG. 5, the fifth-order ripple occurs when the distance between the second reflector 9B and the third reflector 9C is within or near the range of the distance X5. Plots indicating the fifth-order ripple are not located within the range indicated by the hatching. Specifically, the fifth-order ripple occurs on the higher frequency side relative to the pass band when the above distance is within the range of the distance X5. On the other hand, the fifth-order ripple occurs in the pass band when the above distance is longer than the distance X5. Thus, occurrence of a ripple in the pass band can be reduced or prevented when the above distance is within the range of the distance X5.

The sixth-order ripple occurs when the distance between the second reflector 9B and the third reflector 9C is within or near the range of the distance X6. Plots indicating the sixth-order ripple are not located within the range indicated by the hatching. Specifically, the sixth-order ripple occurs on the higher frequency side relative to the pass band when the above distance is within the range of the distance X6. On the other hand, the sixth-order ripple occurs in the pass band when the above distance is longer than the distance X6. Thus, occurrence of a ripple in the pass band can be reduced or prevented when the above distance is within the range of the distance X6.

The seventh-order ripple occurs when the distance between the second reflector 9B and the third reflector 9C is within or near the range of the distance X7. Plots indicating the seventh-order ripple are not located within the range indicated by the hatching. Specifically, the seventh-order ripple occurs on the higher frequency side relative to the pass band when the above distance is within the range of the distance X7. On the other hand, the seventh-order ripple occurs in the pass band when the above distance is longer than the distance X7. Thus, occurrence of a ripple in the pass band can be reduced or prevented when the above distance is within the range of the distance X7.

When the distance between the second reflector 9B and the third reflector 9C is within or near the range of the distance X5, not only the fifth-order ripple but also the sixth-order ripple occurs. However, ripples other than the fifth-order ripple are very small when the above distance is within or near the range of the distance X5. Thus, even when a ripple other than the fifth-order ripple occurs in the case in which the above distance is within the range of the distance X5, the filter characteristics of the acoustic wave device 10 hardly degrades. Similarly, ripples other than the sixth-order ripple are very small when the above distance is within the range of the distance X6. Ripples other than the seventh-order ripple are very small when the above distance is within the range of the distance X7.

As described above, a large ripple periodically occurs with respect to the distance between the second reflector 9B and the third reflector 9C. The order of unwanted waves that are amplified by acoustic coupling and cause the large ripple differs depending on the above distance. This also applies to cases in which the order is not in the range of five to seven. Each dashed line in FIG. 5 is a virtual line indicating the periodicity of the ripple with respect to the above distance. The respective dashed lines indicate approximate frequencies at which a ripple occurs when the order is in the range of five to seven and when the order is not in the range of five to seven.

Here, the exact frequency at which a ripple occurs is indicated by each plot. Each dashed line in FIG. 5 indicates the periodicity of the ripple, and although each dashed line passes through the range indicated by the hatching, it does not immediately mean that the filter characteristics is degraded. As described above, the plots at which large ripples occur are not located within the range indicated by the hatching.

From the above, occurrence of a ripple in the pass band can be reduced or prevented by the distance between the second reflector 9B and the third reflector 9C being the distance Xn within the range represented by Formula 1. This is because of the following reason.

When the value of the round-trip distance between the second reflector 9B and the third reflector 9C is an integer multiple of the value of a length obtained by averaging the wavelengths λa and λb, a ripple due to acoustic coupling occurs in the vicinity of the upper end of a stop band. That is, the above ripple occurs in the vicinity of the upper end of the stop band when the distance between the second reflector 9B and the third reflector 9C is Yn, and Yn×2=[(λa+λb)/2]×n, that is, Yn=[(λa+λb)/4]×n.

In the present specification, the term “stop band” refers to a band determined by the period of a metal grating having a periodic structure. The upper end of the stop band is the highest frequency in the stop band. The term “vicinity of the upper end of the stop band” used herein may refer to the vicinity of the upper end of the stop band in the first acoustic wave resonator 1A or to the vicinity of the upper end of the stop band in the second acoustic wave resonator 1B. In general, the vicinity of the upper end of the stop band in an acoustic wave resonator used in a filter device is located on the higher frequency side relative to the highest frequency of the pass band of the filter device.

When the distance between the second reflector 9B and the third reflector 9C deviates from the distance Yn, the frequency at which the ripple due to acoustic coupling occurs shifts from the vicinity of the upper end of the stop band toward the lower frequency side. However, the inventor of example embodiments of the present invention has discovered that the frequency at which the ripple due to acoustic coupling occurs appears on the higher frequency side relative to the pass band when the distance between the second reflector 9B and the third reflector 9C is longer than Yn×(λa/λb) and shorter than Yn×(λb/λa). This range is represented by Formula 1.

$$\frac{λ a + λ b}{4} \times n \times \frac{λ a}{λ b} < Xn < \frac{λ a + λ b}{4} \times n \times \frac{λ b}{λ a} \qquad Formula 1$$

The occurrence of a ripple in the pass band can be reduced or prevented by the distance between the second reflector 9B and the third reflector 9C being the distance Xn within the range represented by Formula 1. That is, it is possible to reduce or prevent degradation of the filter characteristics of the acoustic wave device 10 without providing a structure between the first acoustic wave resonator 1A and the second acoustic wave resonator 1B. Accordingly, size reduction of the acoustic wave device 10 can be achieved.

In example embodiments the present invention, it is preferable that λa/λb, which is the wavelength ratio of the wavelength λa to the wavelength λb, and λb/λa, which is the wavelength ratio of the wavelength λb to the wavelength λa, fall within the following ranges. Specifically, for example, it is preferable that about 0.9 (λa/λb)<about 1 and about 1<(λb/λa)≤about 1.1. This can more reliably reduce or prevent occurrence of a ripple in the pass band. An example of a case in which the wavelength ratio λa/λb is set to about 0.98 and the wavelength ratio λb/λa is set to about 1.02 is shown below. The result of the first comparative example relating to the comparison shown in FIG. 4 is also shown together.

FIG. 6 is a diagram showing the attenuation-frequency characteristic in the case in which the wavelength ratio λa/λb is about 0.98 and the wavelength ratio λb/λa is about 1.02 in the first example embodiment and in the first comparative example.

As shown in FIG. 6, it can be seen that a ripple occurs on the higher frequency side relative to the pass band when the wavelength ratio λa/λb is about 0.98 and the wavelength ratio λb/λa is about 1.02. As described above, in example embodiments of the present invention, λa<λb. Accordingly, (λa/λb)<1 and (λb/λa)>1. Thus, by satisfying about 0.9≤(λa/λb)<about 1 and about 1<(λb/λa)≤about 1.1, the occurrence of a ripple in the pass band can be more reliably reduced or prevented and degradation of the filter characteristics can be reduced or prevented. In addition, size reduction of the acoustic wave device 10 can be achieved.

Further, the attenuation-frequency characteristic in a case of n=3 is shown. The result of the first comparative example relating to the comparison shown in FIG. 4 is also shown together.

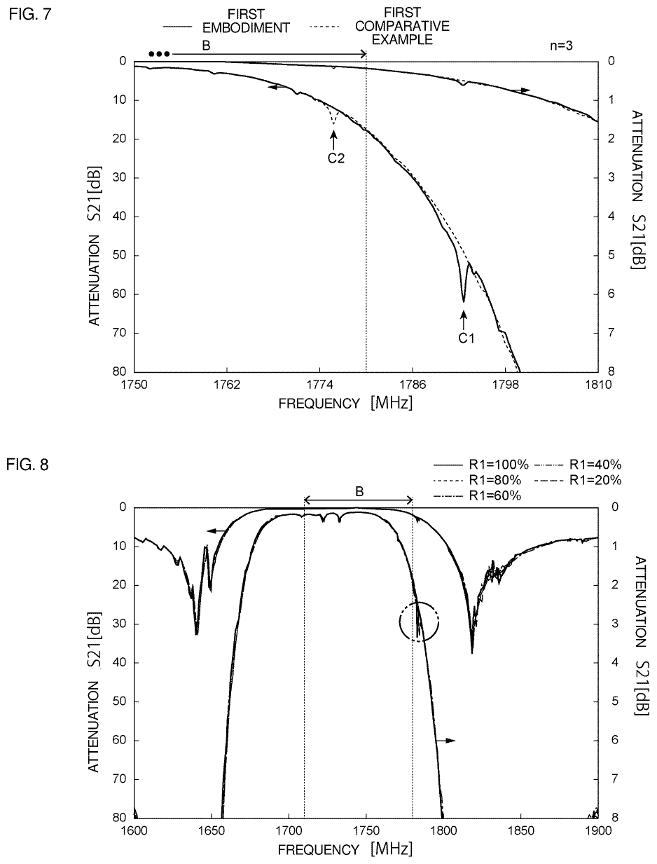

FIG. 7 is a diagram showing the attenuation-frequency characteristic in the case in which n=3 in the first example embodiment and in the first comparative example.

As shown in FIG. 7, it can be seen that a ripple occurs on the higher frequency side relative to the pass band when n=3. In example embodiments of the present invention, it is preferable that n≤3. This can shorten the distance between the second reflector 9B and the third reflector 9C. Accordingly, size reduction of the acoustic wave device 10 can be effectively achieved. In addition, the occurrence of a ripple in the pass band can be more reliably reduced or prevented and degradation of the filter characteristics of the acoustic wave device 10 can be reduced or prevented.

It is more preferable that n=1. This makes it possible to reduce or prevent degradation of the filter characteristics of the acoustic wave device 10 and further achieve size reduction of the acoustic wave device 10.

As shown in FIG. 2, in the first example embodiment, in the first orthogonal direction dx1, the plurality of reflector electrode fingers 9c in the second reflector 9B and the plurality of reflector electrode fingers 9f in the third reflector 9C overlap each other. Specifically, in the first orthogonal direction dx1, almost all portions of the plurality of reflector electrode fingers of the second reflector 9B and the third reflector 9C overlap each other. Specifically, this is as follows.

Dimensions of the plurality of reflector electrode fingers 9c in the second reflector 9B and the plurality of reflector electrode fingers 9f in the third reflector 9C are defined as follows. L1 is defined as the dimension of the plurality of reflector electrode fingers 9c in the second reflector 9B along the first extension direction dy1. L2 is defined as the dimension of the plurality of reflector electrode fingers 9f in the third reflector 9C along the first extension direction dy1. L1x is defined as the dimension, along the first extension direction dy1, of a portion that overlaps the plurality of reflector electrode fingers 9f in the third reflector 9C in the first orthogonal direction dx1 in the plurality of reflector electrode fingers 9c in the second reflector 9B. L2x is defined as the dimension, along the first extension direction dy1, of a portion that overlaps the plurality of reflector electrode fingers 9c in the second reflector 9B in the first orthogonal direction dx1 in the plurality of reflector electrode fingers 9f in the third reflector 9C.

In the acoustic wave device 10 of the first example embodiment, L1<L2 and L1x=L2x. Further, the dimension L1x is about 100% of the dimension L1, and the dimension L2x is about 97.3% of the dimension L2. In example embodiments of the present invention, in the first orthogonal direction dx1, the plurality of reflector electrode fingers 9c in the second reflector 9B and the plurality of reflector electrode fingers 9f in the third reflector 9C are not necessarily required to overlap each other in almost all portions. However, it is preferable that the dimension L1x is about 20% or more of the dimension L1 and the dimension L2x is about 20% or more of the dimension L2. In this case, the ripple due to acoustic coupling is large. In contrast, in example embodiments of the present invention, the frequency at which this ripple occurs can be positioned outside the pass band. Thus, in the above case, example embodiments of the present invention are particularly suitable. Details thereof are shown below.

An examination was conducted using an acoustic wave device having the same or substantially the same configuration as that of the first example embodiment except for a ratio R1 and a ratio R2, where R1 is the ratio of the dimension L1x to the dimension L1 and R2 is the ratio of the dimension L2x to the dimension L2. R1 is defined as (L1x/L1)×100 [%]. R2 is defined as (L2x/L2)×100 [%]. In this acoustic wave device, the attenuation-frequency characteristic was measured each time the ratio R1 was varied. Specifically, the ratio R1 was varied in increments of about 20% within a range of about 20% to about 100%, inclusive. In this acoustic wave device, the ratio R2 increases as the ratio R1 increases. Thus, in this examination, both the ratio R1 and the ratio R2 were varied.

FIG. 8 is a diagram showing a relationship between the ratio R1 and the attenuation-frequency characteristic.

As shown in FIG. 8, even when the ratio R1 varies, the attenuation-frequency characteristic does not significantly change as a whole. However, the magnitude of a ripple enclosed by a circle of a dash-dot-dot line in FIG. 8 changes. This ripple is due to acoustic coupling.

Further, in the above acoustic wave device, an admittance-frequency characteristic in the vicinity of the frequency at which the ripple due to acoustic coupling occurs was measured each time the ratio R1 was varied. Specifically, the ratio R1 was varied in increments of about 20% within a range of about 0% to about 100%, inclusive.

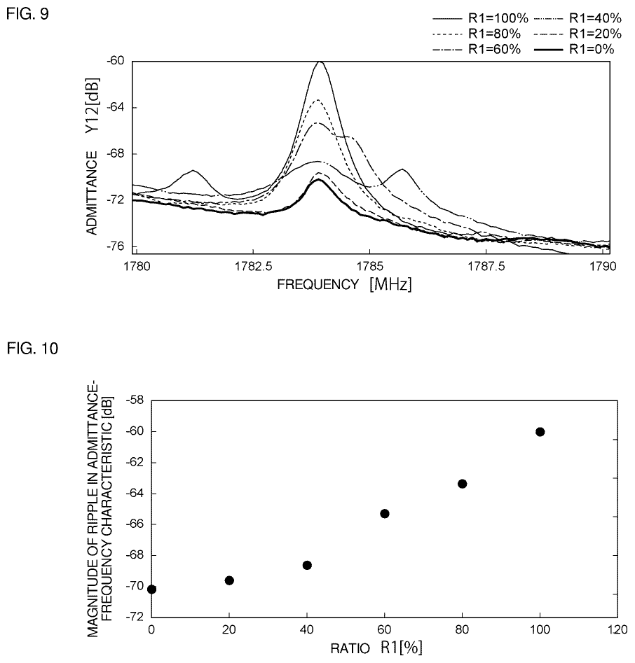

FIG. 9 is a diagram showing a relationship between the ratio R1 and the admittance-frequency characteristic. FIG. 10 is a diagram showing a relationship between the ratio R1 and the magnitude of the ripple due to acoustic coupling.

As shown in FIGS. 9 and 10, the ripple due to acoustic coupling becomes larger as the ratio R1 increases. Further, when the ratio R1 is about 20% or more, the ripple is larger than that when the ratio R1 is about 0%. Thus, when the ratio R1 is about 20% or more and the ripple due to acoustic coupling occurs in the pass band, there is a possibility that the filter characteristics of the acoustic wave device is significantly degraded. The same applies to a case in which the ratio R2 is about 20% or more. In contrast, in example embodiments of the present invention, the frequency at which the ripple due to acoustic coupling occurs can be positioned outside the pass band, and degradation of the filter characteristics of the acoustic wave device can be reduced or prevented. Accordingly, for example, example embodiments of the present invention are particularly suitable when the ratio R1 is about 20% or more and the ratio R2 is about 20% or more.

It is more preferable, for example, that the ratio R1 is about 40% or more and the ratio R2 is about 40% or more. It is still more preferable, for example, that the ratio R1 is about 60% or more and the ratio R2 is about 60% or more. It is even more preferable, for example, that the ratio R1 is about 80% or more and the ratio R2 is about 80% or more. In these cases, example embodiments of the present invention are even more suitable.

Each busbar of the first IDT electrode 8A shown in FIG. 2 includes a plurality of openings. Details of this configuration are described below.

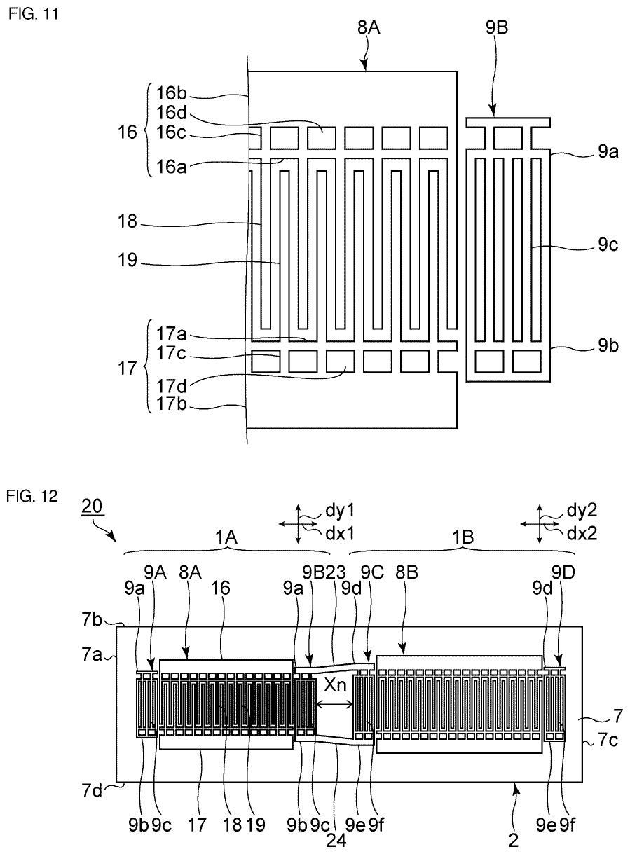

FIG. 11 is a schematic plan view showing a portion of the first IDT electrode and the second reflector in the first example embodiment.

A plurality of openings 16d are provided in the first busbar 16 in the first IDT electrode 8A. The plurality of openings 16d are arranged in the electrode finger orthogonal direction.

Specifically, the first busbar 16 includes a first inner busbar portion 16a, a first outer busbar portion 16b, and a plurality of first connection portions 16c. The first inner busbar portion 16a and the first outer busbar portion 16b are opposed to each other. Of the first inner busbar portion 16a and the first outer busbar portion 16b, the first inner busbar portion 16a is located on the second busbar 17 side. The plurality of first connection portions 16c connect the first inner busbar portion 16a and the first outer busbar portion 16b. The openings 16d are each an opening surrounded by the first inner busbar portion 16a, the first outer busbar portion 16b, and the plurality of first connection portions 16c.

Similarly, the second busbar 17 also includes a second inner busbar portion 17a, a second outer busbar portion 17b, and a plurality of second connection portions 17c. A plurality of openings 17d are provided in the second busbar 17. The plurality of openings 17d are arranged in the electrode finger orthogonal direction. The openings 17d are each an opening surrounded by the second inner busbar portion 17a, the second outer busbar portion 17b, and the plurality of second connection portions 17c. Further, each busbar in the second IDT electrode 8B shown in FIG. 2 is also provided similarly to each busbar in the first IDT electrode 8A.

Moreover, each of the first reflector busbars 9a and the second reflector busbars 9b in the first reflector 9A and the second reflector 9B also includes at least one opening. The openings of the first reflector busbars 9a in the first reflector 9A and the second reflector 9B are disposed alongside the openings 16d of the first busbar 16 in the first IDT electrode 8A in the first orthogonal direction dx1. The openings of the second reflector busbars 9b in the first reflector 9A and the second reflector 9B are disposed alongside the openings 17d of the second busbar 17 in the first IDT electrode 8A in the first orthogonal direction dx1.

The third reflector busbars 9d and the fourth reflector busbars 9e in the third reflector 9C and the fourth reflector 9D are provided similarly to the first reflector busbars 9a and the second reflector busbars 9b in the first reflector 9A and the second reflector 9B.

However, each busbar in the first IDT electrode 8A and the second IDT electrode 8B is not required to include the opening. The first reflector busbars 9a and the second reflector busbars 9b in the first reflector 9A and the second reflector 9B and the third reflector busbars 9d and the fourth reflector busbars 9e in the third reflector 9C and the fourth reflector 9D are not required to include the opening.

As shown in FIG. 2, the shape of the piezoelectric layer 7 in plan view is rectangular or substantially rectangular. In the present specification, the term “plan view” refers to viewing from a direction corresponding to the upper side in FIG. 3 along the lamination direction of support 3 and the piezoelectric layer 7. In FIG. 3, for example, of the support substrate 4 side and the piezoelectric layer 7 side, the piezoelectric layer 7 side is the upper side.

Referring back to FIG. 2, the piezoelectric layer 7 includes four sides in plan view. Specifically, the four sides include a first side 7a, a second side 7b, a third side 7c, and a fourth side 7d. The first side 7a and the third side 7c are opposed to each other. The second side 7b and the fourth side 7d are opposed to each other.

Although omitted in FIG. 2, for example, an acoustic wave resonator other than the first acoustic wave resonator 1A and the second acoustic wave resonator 1B is provided between the first acoustic wave resonator 1A and the second side 7b or between the first acoustic wave resonator 1A and the fourth side 7d. This is also the same or substantially the same in other example embodiments described later and the like.

The first orthogonal direction dx1 is parallel or substantially parallel to a direction in which some of the sides of the piezoelectric layer 7 extend. Specifically, the first orthogonal direction dx1 is parallel or substantially parallel to a direction in which the second side 7b and the fourth side 7d of the piezoelectric layer 7 extend. Similarly, the second orthogonal direction dx2 is parallel or substantially parallel to the direction in which the second side 7b and the fourth side 7d of the piezoelectric layer 7 extend. However, in example embodiments of the present invention, at least one of the first orthogonal direction dx1 or the second orthogonal direction dx2 is not required to be parallel or substantially parallel to the direction in which the second side 7b or the fourth side 7d extends.

Examples of materials of the respective layers in the piezoelectric substrate 2 shown in FIG. 3 are shown below. In the present specification, the term “main component” refers to a component having a proportion exceeding 50 wt % in an element, component, or portion, etc. The material of the above main component may be provided in any of a single-crystal state, a polycrystalline state, and an amorphous state or in a state in which these states are mixed.

As a material of the support substrate 4, for example, the following materials can also be used: a piezoelectric body such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiALON, a dielectric such as aluminum oxide, silicon oxynitride, diamond-like carbon (DLC), or diamond, a semiconductor such as silicon, or a material including the above material as a main component. The spinel includes, for example, an aluminum compound including oxygen and one or more of Mg, Fe, Zn, Mn, or the like. Examples of the above spinel include MgAl₂O₄, FeAl₂O₄, ZnAl₂O₄, or MnAl₂O₄. The same applies to the spinel provided as an example of a material of the first intermediate layer 5 described later. In the first example embodiment, the support substrate 4 is a silicon support substrate, for example.

In the first example embodiment, the first intermediate layer 5 is a high acoustic velocity film. The term “high acoustic velocity film” refers to a film in which the acoustic velocity of a propagating bulk wave is relatively high. Specifically, the acoustic velocity of a bulk wave propagating through the high acoustic velocity film is higher than the acoustic velocity of an acoustic wave propagating through the piezoelectric layer 7. As a material of the first intermediate layer 5, which is the high acoustic velocity film, for example, the following materials can be used: a piezoelectric body such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiALON, a dielectric such as aluminum oxide, silicon oxynitride, diamond-like carbon (DLC), or diamond, a semiconductor such as silicon, or a material including the above material as a main component. In the first example embodiment, the first intermediate layer 5 is a silicon nitride layer, for example.

On the other hand, the second intermediate layer 6 is a low acoustic velocity film. The term “low acoustic velocity film” refers to a film in which the acoustic velocity of a propagating bulk wave is relatively low. Specifically, the acoustic velocity of a bulk wave propagating through the low acoustic velocity film is lower than the acoustic velocity of a bulk wave propagating through the piezoelectric layer 7. As a material of the second intermediate layer 6, which is the low acoustic velocity film, for example, the following materials can be used: a dielectric such as glass, silicon oxide, silicon oxynitride, lithium oxide, tantalum oxide, or a compound obtained by adding fluorine, carbon, or boron to silicon oxide, or a material including the above material as a main component. In the first example embodiment, the second intermediate layer 6 is a silicon oxide layer, for example.

As a material of the piezoelectric layer 7, for example, lithium tantalate, lithium niobate, zinc oxide, aluminum nitride, quartz, lead zirconate titanate (PZT), or the like can be used. In particular, it is preferable that lithium tantalate or lithium niobate is used as the material of the piezoelectric layer 7. In the first example embodiment, 42° Y-cut lithium tantalate is used as the material of the piezoelectric layer 7. The cut-angle of the piezoelectric layer 7 is not limited to the above.

In the acoustic wave device 10, the first intermediate layer 5, which is the high acoustic velocity film, the second intermediate layer 6, which is the low acoustic velocity film, and the piezoelectric layer 7 are laminated in that order. This allows energy of the acoustic wave to be effectively confined in the piezoelectric layer 7. The support 3 is not necessarily required to include the first intermediate layer 5 and the second intermediate layer 6.

In example embodiments of the present invention, a dielectric film may be provided on the piezoelectric layer 7 so as to cover the first IDT electrode 8A, the first reflector 9A, and the second reflector 9B. Similarly, a dielectric film may be provided on the piezoelectric layer 7 so as to cover the second IDT electrode 8B, the third reflector 9C, and the fourth reflector 9D. With this configuration, each IDT electrode and each reflector are less likely to be damaged. As a material of the dielectric film, for example, silicon oxide, silicon nitride, silicon oxynitride, or the like can be used.

FIG. 12 is a schematic plan view showing the first acoustic wave resonator and the second acoustic wave resonator in an acoustic wave device according to a second example embodiment of the present invention.

The present example embodiment is different from the first example embodiment in that the second reflector 9B and the third reflector 9C are electrically connected. Except for the above point, an acoustic wave device 20 of the present example embodiment has the same or substantially the same configuration as the acoustic wave device 10 of the first example embodiment.

A connection electrode 23 and a connection electrode 24 are disposed on the piezoelectric layer 7. The connection electrode 23 and the connection electrode 24 electrically connect the second reflector 9B and the third reflector 9C. Specifically, the connection electrode 23 connects the first reflector busbar 9a in the second reflector 9B and the third reflector busbar 9d in the third reflector 9C. The connection electrode 24 connects the second reflector busbar 9b in the second reflector 9B and the fourth reflector busbar 9e in the third reflector 9C.

Also in the present example embodiment, similarly to the first example embodiment, it is possible to reduce or prevent degradation of the filter characteristics of the acoustic wave device 20 and achieve size reduction of the acoustic wave device 20.

In the acoustic wave devices of the first and second example embodiments and the like, the first orthogonal direction dx1 and the second orthogonal direction dx2 are parallel or substantially parallel to each other. However, the first orthogonal direction dx1 and the second orthogonal direction dx2 are not necessarily required to be parallel or substantially parallel to each other. An example of an arrangement of the first acoustic wave resonator and the second acoustic wave resonator in which the first orthogonal direction dx1 and the second orthogonal direction dx2 are not parallel or substantially parallel to each other is shown in a third example embodiment.

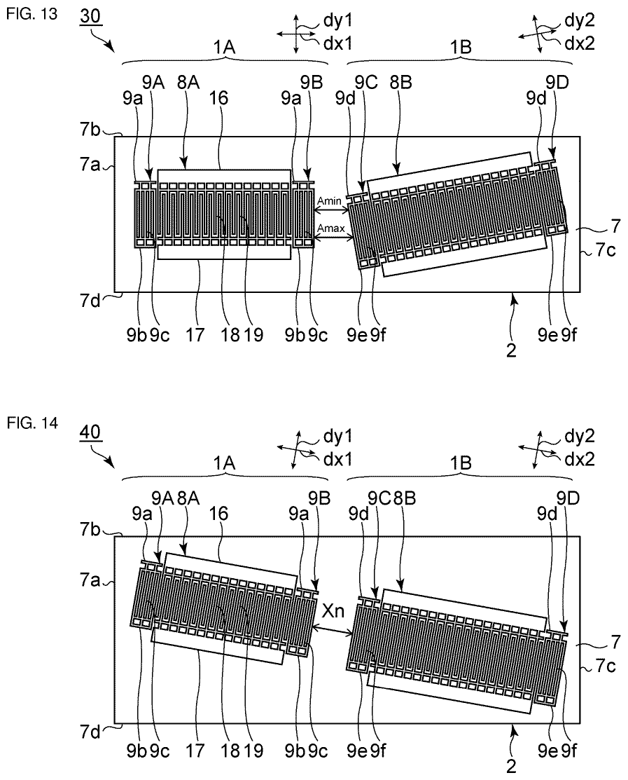

FIG. 13 is a schematic plan view showing the first acoustic wave resonator and the second acoustic wave resonator in an acoustic wave device according to a third example embodiment of the present invention.

The present example embodiment is different from the first example embodiment in that the electrode finger orthogonal direction in the first IDT electrode 8A is not parallel or substantially parallel to the electrode finger orthogonal direction in the second IDT electrode 8B. The present example embodiment is different from the first example embodiment also in that the first orthogonal direction dx1 in the first reflector 9A and the second reflector 9B is not parallel or substantially parallel to the second orthogonal direction dx2 in the third reflector 9C and the fourth reflector 9D. Except for the above points, an acoustic wave device 30 of the present example embodiment has the same or substantially the same configuration as the acoustic wave device 10 of the first example embodiment.

The first orthogonal direction dx1 is orthogonal or substantially orthogonal to a direction in which the first side 7a and the third side 7c in the piezoelectric layer 7 extend. Further, the first orthogonal direction dx1 is parallel or substantially parallel to a direction in which the second side 7b and the fourth side 7d in the piezoelectric layer 7 extend. Thus, for example, the smallest angle between the first orthogonal direction dx1 and the direction in which the sides in the piezoelectric layer 7 extend is about 0°. On the other hand, the second orthogonal direction dx2 is parallel or substantially parallel to none of the directions in which the sides in the piezoelectric layer 7 extend. Thus, for example, the smallest angle formed by the second orthogonal direction dx2 and the direction in which the sides in the piezoelectric layer 7 extend is greater than about 0°. Accordingly, in the present example embodiment, of the first orthogonal direction dx1 and the second orthogonal direction dx2, the first orthogonal direction dx1 is the direction having the smaller of the smallest angles between the direction in which the sides of the piezoelectric layer 7 extend.

Here, a distance between the second reflector 9B and the third reflector 9C is defined as follows. That is, this distance is defined as a distance between the second reflector 9B and the third reflector 9C in the direction having the smaller of the smallest angles formed with the direction in which the sides of the piezoelectric layer 7 extend, among the first orthogonal direction dx1 and the second orthogonal direction dx2. In the present example embodiment, the distance between the second reflector 9B and the third reflector 9C is a distance between the second reflector 9B and the third reflector 9C in the first orthogonal direction dx1.

However, the distance between the second reflector 9B and the third reflector 9C in the acoustic wave device 30 is not constant. In this case, the shortest distance between the second reflector 9B and the third reflector 9C is defined as Amin, and the longest distance therebetween is defined as Amax. In addition, a mean value (Amin+Amax)/2 of these distances is defined as the distance between the second reflector 9B and the third reflector 9C. From the above, in the present example embodiment, the mean value of the shortest distance Amin and the longest distance Amax in the first orthogonal direction dx1 between the second reflector 9B and the third reflector 9C is the distance between the second reflector 9B and the third reflector 9C.

In the acoustic wave device 30, (Amin+Amax)/2 as the distance between the second reflector 9B and the third reflector 9C is the distance Xn within the range represented by Formula 1, where n is any natural number. Accordingly, similarly to the first example embodiment, it is possible to reduce or prevent degradation of the filter characteristics of the acoustic wave device 30 and achieve size reduction of the acoustic wave device 30.

It is preferable that an angle between the first orthogonal direction dx1 and the second orthogonal direction dx2 is, for example, about 150 or less. In this case, a large ripple due to acoustic coupling is likely to occur. In contrast, in example embodiments of the present invention, the frequency at which this ripple occurs can be positioned outside the pass band. Therefore, in the above case, example embodiments of the present invention are particularly suitable.

Further, an example of an arrangement of the first acoustic wave resonator and the second acoustic wave resonator different from the above arrangement is shown in a fourth example embodiment of the present invention.

FIG. 14 is a schematic plan view showing the first acoustic wave resonator and the second acoustic wave resonator in an acoustic wave device according to a fourth example embodiment.

The present example embodiment is different from the first example embodiment in the angles between the electrode finger orthogonal direction in the first IDT electrode 8A and the electrode finger orthogonal direction in the second IDT electrode 8B and the directions in which the sides of the piezoelectric layer 7 extend. The present example embodiment is different from the first example embodiment also in the angles between the first orthogonal direction dx1 in the first reflector 9A and the second reflector 9B and the directions in which the sides of the piezoelectric layer 7 extend. Moreover, the present example embodiment is different from the first example embodiment also in the angles between the second orthogonal direction dx2 in the third reflector 9C and the fourth reflector 9D and the directions in which the sides of the piezoelectric layer 7 extend. Except for the above points, an acoustic wave device 40 of the present example embodiment has the same or substantially the same configuration as the acoustic wave device 10 of the first example embodiment.

In the present example embodiment, the first orthogonal direction dx1 and the second orthogonal direction dx2 are parallel or substantially parallel to each other. Thus, the distance between the second reflector 9B and the third reflector 9C is a distance between the second reflector 9B and the third reflector 9C in the first orthogonal direction dx1 and the second orthogonal direction dx2.

Also in the present example embodiment, similarly to the first example embodiment, it is possible to reduce or prevent degradation of the filter characteristics of the acoustic wave device 40 and achieve size reduction of the acoustic wave device 40.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer;
a first interdigital transducer (IDT) electrode on the piezoelectric layer;
a second IDT electrode on the piezoelectric layer;
a first reflector and a second reflector on the piezoelectric layer and opposed to each other with the first IDT electrode interposed therebetween, and each including a plurality of reflector electrode fingers; and
a third reflector and a fourth reflector on the piezoelectric layer and opposed to each other with the second IDT electrode interposed therebetween, and each including a plurality of reflector electrode fingers; wherein
of the first reflector and the second reflector, the second reflector is located on a second IDT electrode side, and, of the third reflector and the fourth reflector, the third reflector is located on a first IDT electrode side;
when a direction orthogonal or substantially orthogonal to a direction in which the plurality of reflector electrode fingers in the second reflector extend is defined as an orthogonal direction, the plurality of reflector electrode fingers in the second reflector and the plurality of reflector electrode fingers in the third reflector overlap each other in the orthogonal direction;
when M is defined as a median of all of center-to-center distances between the reflector electrode fingers adjacent to each other as a plurality of pairs of the reflector electrode fingers in each of the second reflector and the third reflector, a mean value of the center-to-center distances within a range of M±about 40% is defined as a mean center-to-center distance, and λa<λb, where λa is a wavelength defined by the mean center-to-center distance in the second reflector and λb is a wavelength defined by the mean center-to-center distance in the third reflector; and
a distance between the second reflector and the third reflector is a distance Xn within a range represented by the Formula 1, where n is any natural number:
$$\frac{λ a + λ b}{4} \times n \times \frac{λ a}{λ b} < Xn < \frac{λ a + λ b}{4} \times n \times \frac{λ b}{λ a} . \qquad Formula 1$$

2. The acoustic wave device according to claim 1, wherein about 0.9≤(λa/λb)<about 1 and about 1<(λb/λa)≤about 1.1.

3. The acoustic wave device according to claim 1, wherein n≤3.

4. The acoustic wave device according to claim 3, wherein n=1.

5. The acoustic wave device according to claim 1, further comprising a connection electrode electrically connecting the second reflector and the third reflector.

6. The acoustic wave device according to claim 1, wherein when a direction in which the plurality of reflector electrode fingers in the second reflector extend is defined as an extension direction and L1 is defined as a dimension of the plurality of reflector electrode fingers in the second reflector along the extension direction, and L1x is defined as a dimension, along the extension direction, of a portion that overlaps the plurality of reflector electrode fingers in the third reflector in the orthogonal direction in the plurality of reflector electrode fingers in the second reflector, the dimension L1x is about 20% or more of the dimension L1; and
when L2 is defined as a dimension of the plurality of reflector electrode fingers in the third reflector along the extension direction, and L2x is defined as a dimension, along the extension direction, of a portion that overlaps the plurality of reflector electrode fingers in the second reflector in the orthogonal direction in the plurality of reflector electrode fingers in the third reflector, the dimension L2x is about 20% or more of the dimension L2.

7. The acoustic wave device according to claim 1, wherein
the piezoelectric substrate includes a support substrate; and
the piezoelectric layer is directly or indirectly provided on the support substrate.

8. The acoustic wave device according to claim 1, wherein
the piezoelectric substrate includes a support and the piezoelectric layer; and
the support includes a support substrate, a first intermediate layer and a second intermediate layer.

9. The acoustic wave device according to claim 7, wherein the support substrate includes silicon.

10. The acoustic wave device according to claim 8, wherein the support substrate includes silicon, the first intermediate layer includes silicon nitride, and the second intermediate layer includes silicon oxide.

11. The acoustic wave device according to claim 1, wherein each of the first and second IDT electrodes and the first, second, third, and fourth reflectors includes a multilayer metal film.

12. The acoustic wave device according to claim 11, wherein the multilayer film includes a Ti layer and an AlCu layer.

13. The acoustic wave device according to claim 1, wherein
the first IDT electrode includes first and second busbars and a plurality of first and second electrode fingers;
one end of each of the plurality of first electrode fingers is connected to the first busbar; and
one end of each of the plurality of second electrode fingers is connected to the second busbar.

14. The acoustic wave device according to claim 13, wherein the first busbar includes a plurality of openings.

15. The acoustic wave device according to claim 13, wherein the first busbar includes a first inner busbar portion, a first outer busbar portion and a plurality of first connection portions extending between the first inner busbar portion and the first outer busbar portion.

16. The acoustic wave device according to claim 13, wherein the second busbar includes a plurality of openings.

17. The acoustic wave device according to claim 13, wherein the second busbar includes a second inner busbar portion, a second outer busbar portion and a plurality of second connection portions extending between the second inner busbar portion and the second outer busbar portion.

18. The acoustic wave device according to claim 1, wherein
the first reflector includes first busbars;
the second reflector includes second busbars;
the third reflector includes third busbars; and
the fourth reflector includes fourth busbars.

19. The acoustic wave device according to claim 18, wherein each of the first and second busbars includes at least one opening.

20. The acoustic wave device according to claim 18, wherein each of the third and fourth busbars includes at least one opening.
